(19) United States
(12) Patent Application Publication
(10) Pub. No.: US 2016/0090651 A1
(43) Pub. Date: Mar. 31, 2016

(54) SUBSTRATE PROCESSING APPARATUS

(71) Applicant: HITACHI KOKUSAI ELECTRIC INC., Tokyo (JP)

(72) Inventors: Hiroshi ASHIHARA, Toyama-shi (JP); Naofumi OHASHI, Toyama (JP)

(73) Assignee: HITACHI KOKUSAI ELECTRIC INC., Tokyo (JP)

(21) Appl. No.: 14/841,106

(22) Filed: Aug. 31, 2015

(30) Foreign Application Priority Data
Sep. 29, 2014 (JP) 2014198518

(51) Int. Cl. C23C 16/52; C23C 16/458; C23C 16/448; C23C 16/455

(52) U.S. Cl. CPC C23C 16/52; C23C 16/45544; C23C 16/4586; C23C 16/4482

(57) ABSTRACT

A substrate processing apparatus includes a processing chamber configured to accommodate a substrate therein; a first processing gas supply part configured to supply a first processing gas to the substrate, the first processing gas supply part including a vaporizer configured to vaporize a first processing gas precursor into the first processing gas; a second processing gas supply part configured to supply a second processing gas to the substrate; a vaporizer remaining amount measuring part configured to measure a remaining amount of the first processing gas precursor within the vaporizer; and a control part configured to adjust a number of cycles for supplying the first processing gas and the second processing gas based on the remaining amount of the first processing gas precursor.

### CROSS-REFERENCE TO RELATED APPLICATION

This application is based upon and claims the benefit of priority from Japanese Patent Application No. 2014-198518, filed on Sep. 29, 2014, the entire contents of which are incorporated herein by reference.

### TECHNICAL FIELD

The present disclosure relates to a substrate processing apparatus.

### BACKGROUND

Along with the high integration of a large scale integrated circuit (hereinafter referred to as an “LSI”), miniaturization of a circuit pattern is underway.

In order to integrate a large number of semiconductor devices within a limited area, the size of the semiconductor devices needs to be reduced. To this end, it may be necessary to reduce the width and spacing of the patterns to be formed.

Due to recent miniaturization, the formation of a uniform film on a microstructure surface, particularly the formation of an oxide film on a surface of a vertically-deep or horizontally-narrow void structure (groove), is reaching a technical limit. Furthermore, due to the miniaturization of transistors, it is necessary to form a thin uniform gate insulation film or gate electrode. Moreover, in order to increase the productivity of semiconductor devices, there is sometimes a need to shorten the processing time per one substrate.

In recent years, the minimum processing dimension (pattern size) of semiconductor devices represented by an LSI, a dynamic random access memory (DRAM) and a flash memory is set to be very small. In a self-aligned double patterning (SADP) method, a spacer film is directly formed on the sidewalls of patterns (projections) fabricated by lithography or on the bottom surfaces between the projections. When forming the spacer film, there is sometimes a need to form a film having no variation in film thickness and having good step coverage on the sidewalls or the bottom surfaces of the patterns. By forming a film having good step coverage, it is possible to make the characteristics of the semiconductor device between grooves uniform thereby limiting variations in the characteristics of the semiconductor device.

### SUMMARY

The present disclosure provides some embodiments of a substrate processing apparatus capable of improving the characteristics of a film formed on a substrate and enhancing the manufacturing throughput, a method of manufacturing a semiconductor device, and a recording medium.

According to one embodiment of the present disclosure, there is provided a substrate processing apparatus including a processing chamber configured to accommodate a substrate therein; a first processing gas supply part configured to supply a first processing gas to the substrate, the first processing gas supply part including a vaporizer configured to vaporize a first processing gas precursor into the first processing gas; a second processing gas supply part configured to supply a second processing gas to the substrate; a vaporizer remaining amount measuring part configured to measure a remaining amount of the first processing gas precursor within the vaporizer; and a control part configured to adjust a number of cycles for supplying the first processing gas and the second processing gas based on the remaining amount of the first processing gas precursor.

### BRIEF DESCRIPTION OF THE DRAWINGS

FIG. 1 is a schematic configuration diagram of a substrate processing apparatus according to one embodiment.

FIG. 2 is a schematic configuration diagram of a gas supply system of the substrate processing apparatus according to one embodiment.

FIG. 3 is a schematic configuration diagram of a controller of the substrate processing apparatus according to one embodiment.

FIG. 4 is a flowchart illustrating a substrate processing process according to one embodiment.

FIG. 5 is a flowchart illustrating a cycle number changing process according to one embodiment.

FIG. 6 is a view illustrating a change of a cycle rate according to one embodiment.

FIG. 7 is a view illustrating a change of a cycle rate according to one embodiment.

FIG. 8 is a schematic configuration diagram of a substrate processing system according to one embodiment.

FIG. 9 is a schematic configuration diagram of a gas system of the substrate processing system according to one embodiment.

### DETAILED DESCRIPTION

Embodiments of the present disclosure will now be described in detail with reference to the drawings.

The present inventors have found the following causes of the problem of variation of films between substrates which occurs along with the thinning of a spacer film. In a film forming method in which a precursor gas and a reaction gas are sequentially supplied, the thickness of a film formed per one cycle of supplying the precursor gas and the reaction gas (namely, a cycle rate) fluctuates. Particularly, when a spacer film has a thickness of about 5 nm or less and a cycle rate is 0.5 Å/cycle, if the cycle rate is slightly changed even in one cycle among the total number of cycles performed in a film forming process, such a change in the cycle rate affects the spacer film.

### First Embodiment

Hereinafter, a first embodiment will be described with reference to the drawings.

### (1) Configuration of Substrate Processing Apparatus

First, descriptions will be made on a substrate processing apparatus according to a first embodiment.

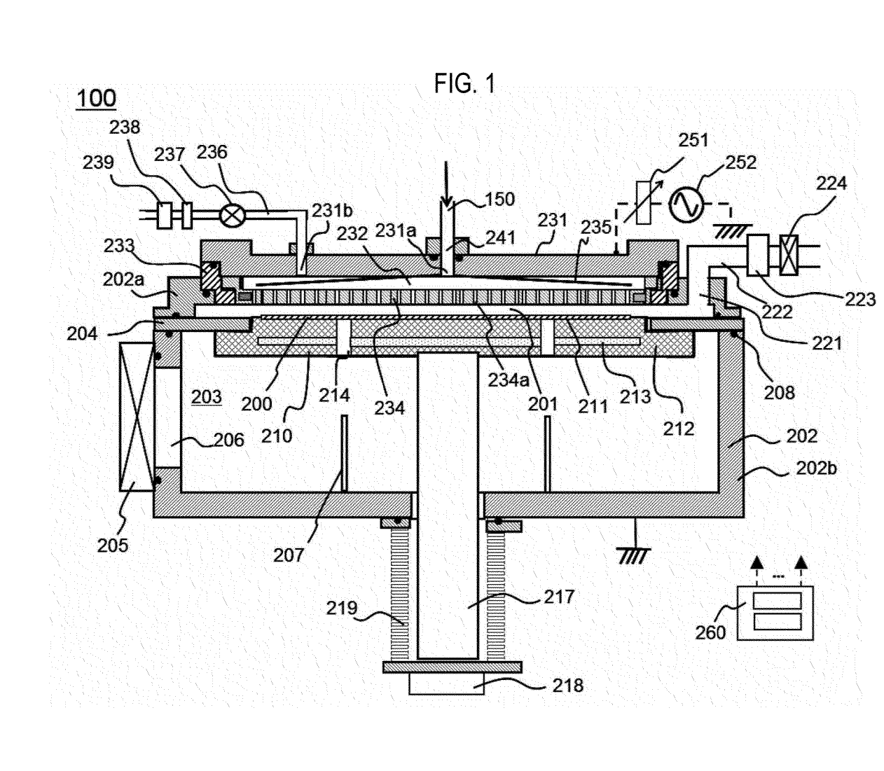

A substrate processing apparatus 100 according to the present embodiment will be described. The substrate processing apparatus 100 is a device for forming an insulation film having a high dielectric constant. As illustrated in FIG. 1, the substrate processing apparatus 100 is configured by a single-substrate-type substrate processing apparatus. In the substrate processing apparatus 100, one of the processes for manufacturing a semiconductor device described above is performed.

As illustrated in FIG. 1, the substrate processing apparatus 100 includes a processing container 202. The processing container 202 is configured by, for example, a flat hermetically-sealed container having a circular horizontal cross section. Furthermore, the processing container 202 is made of a metallic material such as, e.g., aluminum (Al) or stainless steel (SUS), or quartz. A processing space (processing chamber) 201 for processing a wafer 200 such as a silicon wafer or the like as a substrate and a transfer space 203 are formed within the processing container 202. The processing container 202 is formed of an upper container 202a and a lower container 202b. A partition plate 204 is installed between the upper container 202a and the lower container 202b. The space surrounded by the upper container 202a and positioned above the partition plate 204 will be referred to as a processing space A (or a processing chamber) 201. The space surrounded by the lower container 202b and positioned below the partition plate 204 will be referred to as a transfer space 203.

A substrate carry-in/carry-out gate 206 adjoining a gate valve 205 is formed on the side surface of the lower container 202b. The wafer 200 is moved between the transfer space 203 and the transfer chamber (not illustrated) through the substrate carry-in/carry-out gate 206. A plurality of lift pins 207 is installed in the bottom portion of the lower container 202b. In addition, the lower container 202b is grounded.

A substrate support part 210 which supports the wafer 200 is installed within the processing chamber 201. The substrate support part 210 includes a substrate mounting surface 211 which mounts the wafer 200 thereon, a substrate mounting table 212 having the substrate mounting surface 211, and a heater 213 as a heating part. By installing the heating part, it is possible to heat the substrate and to improve the quality of a film formed on the substrate. Through-holes 214 through which the lift pins 207 penetrate may be formed in the substrate mounting table 212 at the locations corresponding to the lift pins 207.

The substrate mounting table 212 is supported by a shaft 217. The shaft 217 penetrates through the bottom portion of the processing container 202. Furthermore, the shaft 217 is connected to a lift mechanism 218 outside the processing container 202. By operating the lift mechanism 218 and moving the shaft 217 and the substrate mounting table 212 up and down, it is possible to move up and down the wafer 200 mounted on the substrate mounting surface 211. In addition, the periphery of the lower end portion of the shaft 217 is covered with a bellows 219. Thus, the inside of the processing chamber 201 is kept hermetically sealed.

When transferring the wafer 200, the substrate mounting table 212 is moved down to the bottom portion of the processing container 202 so that the substrate mounting surface 211 is aligned with a position of the substrate carry-in/carry-out gate 206 (a wafer transfer position). When processing the wafer 200, as illustrated in FIG. 1, the wafer 200 is moved up to a processing position (a wafer processing position) within the processing chamber 201.

Specifically, when the substrate mounting table 212 is moved down to the wafer transfer position, the upper end portions of the lift pins 207 protrude upward from the substrate mounting surface 211 so that the lift pins 207 support the wafer 200 from below. Furthermore, when the substrate mounting table 212 is moved up to the wafer processing position, the lift pins 207 retract from the substrate mounting surface 211 so that the substrate mounting surface 211 supports the wafer 200 from below. Since the lift pins 207 make direct contact with the wafer 200, the lift pins 207 may be made of a material such as, e.g., quartz or alumina. Moreover, lift mechanisms may be installed in the lift pins 207 so that the substrate mounting table 212 and the lift pins 207 are moved relative to each other.

### (Exhaust System)

An exhaust port 221 as a first exhaust part for exhausting the atmosphere of the processing chamber 201 is formed on the side surface of the inner wall of the processing chamber 201 (the upper container 202a). An exhaust pipe 222 is connected to the exhaust port 221. A pressure regulator 223 such as an auto pressure controller (APC) for controlling the internal pressure of the processing chamber 201 at a predetermined pressure and a vacuum pump 224 are sequentially and serially connected to the exhaust pipe 222. A first exhaust part (exhaust line) is mainly configured by the exhaust port 221, the exhaust pipe 222 and the pressure regulator 223. Furthermore, the vacuum pump 224 may be included in the first exhaust part.

### (Gas Introduction Port)

A gas introduction port 241 for supplying various kinds of gases into the processing chamber 201 is formed in an upper surface (a ceiling wall) of a shower head 234 installed in the top portion of the processing chamber 201. The configuration of a gas supply system connected to the gas introduction port 241 will be described later.

### (Gas Dispersion Part)

The shower head 234 (a dispersion plate) as a gas dispersion part is installed between the gas introduction port 241 and the processing chamber 201. The shower head 234 is disposed so as to face the substrate mounting surface 211. The gas introduction port 241 is connected to a cover 231 of the shower head 234. The gas introduced from the gas introduction port 241 is supplied to a buffer space 232 of the shower head 234 through a hole 231a formed in the cover 231. The shower head 234 is made of a material such as, e.g., quartz, alumina, stainless steel or aluminum.

Alternatively, the cover 231 of the shower head 234 may be made of an electrically conductive metal and may be used as an activating part (an exciting part) for exciting the gas exiting within the buffer space 232 or the processing chamber 201. In this case, an insulation block 233 is installed between the cover 231 and the upper container 202a to provide insulation between the cover 231 and the upper container 202a. A matcher 251 and a high-frequency power source 252 may be connected to the electrode (the cover 231) as an activating part so that electromagnetic waves (high-frequency power or microwaves) can be supplied thereto.

A gas guide 235 configured to form a flow of a supplied gas is installed in the buffer space 232. The gas guide 235 has a conical shape with the diameter thereof growing larger from the hole 231a as a vertex toward the dispersion plate 234. The horizontal diameter of the lower end portion of the gas guide 235 is set to extend outward beyond the outermost dispersion holes 234a.

An exhaust pipe 236 as a second exhaust part is connected to the lateral side of the buffer space 232 through a shower head exhaust port 231b. A valve 237 for switching on/off states of exhaust, a pressure regulator 238 such as an auto pressure controller (APC) for controlling the internal pressure of the buffer space 232 at a predetermined pressure and a vacuum pump 239 are sequentially and serially connected to the exhaust pipe 236.

### (Supply System)

A common gas supply pipe 150 (150a, 150b, 150c or 150d which will be described later) is connected to the gas introduction port 241 connected to the cover 231 of the shower head 234. A processing gas, a reaction gas or a purge gas, which will be described later, is supplied from the common gas supply pipe 150.

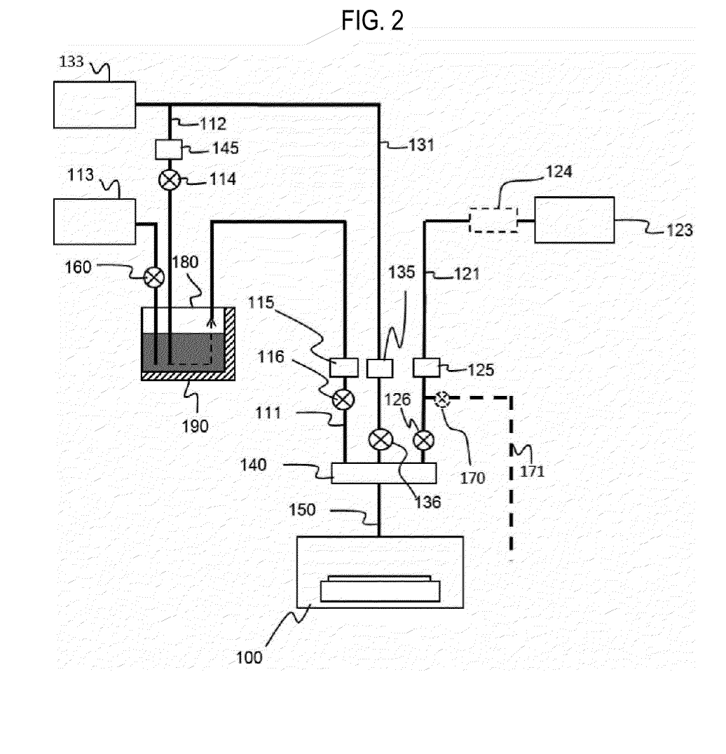

In FIG. 2, there is illustrated a schematic configuration diagram of a first processing gas supply part, a second processing gas supply part and a purge gas supply part.

As illustrated in FIG. 2, a supply pipe collecting part 140 is connected to the common gas supply pipe 150. A first processing gas supply part, a second processing gas supply part and a purge gas supply part are connected to the supply pipe collecting part 140.

### (First Processing Gas Supply Part)

A first processing gas precursor valve 160, a vaporizer 180, a gas supply pipe 111, a mass flow controller (MFC) 115, a valve 116 and a vaporizer remaining amount measuring part 190 are installed in the first processing gas supply part. Moreover, a first processing gas source 113 may be included in the first processing gas supply part. The vaporizer 180 is configured to vaporize a processing gas by supplying a carrier gas to a processing gas precursor of a liquid state and causing the processing gas precursor to bubble.

The carrier gas is supplied from a carrier gas supply pipe 112 connected to a purge gas supply source 133. The flow rate of the carrier gas is adjusted by a mass flow controller 145 installed in the carrier gas supply pipe 112. The carrier gas is supplied to the vaporizer 180 via a gas valve 114. The vaporizer remaining amount measuring part 190 is configured to measure the amount of a processing gas precursor based on the weight and/or height (liquid level) of the processing gas precursor existing within the vaporizer 180. In order to detect the height of the processing gas precursor, at least one among an ultrasonic sensor disposed on the bottom of the vaporizer 180, a floating sensor disposed within the vaporizer 180, an optical sensor (e.g., laser sensor) disposed inside and/or outside the vaporizer 180 may be used. Based on the measurement result of the vaporizer remaining amount measuring part 190, the gas valve 114 is controlled to be opened or closed so that the processing gas precursor existing within the vaporizer 180 is maintained at a predetermined amount.

### (Second Processing Gas Supply Part)

A gas supply pipe 121, a mass flow controller 125 and a valve 126 are installed in the second processing gas supply part. Moreover, a second processing gas source 123 may be included in the second processing gas supply part. In addition, a remote plasma unit (RPU) 124 may be installed so as to activate a second processing gas.

Furthermore, a vent valve 170 and a vent pipe 171 may be installed so as to exhaust an inert reaction gas retained within the gas supply pipe 121.

### (Purge Gas Supply Part)

A gas supply pipe 131, a mass flow controller 135 and a valve 136 are installed in the purge gas supply part. Moreover, a purge gas source 133 may be included in the purge gas supply part.

### (Control Part)

As illustrated in FIG. 1, the substrate processing apparatus 100 includes a controller 260 which controls the operations of the respective parts of the substrate processing apparatus 100.

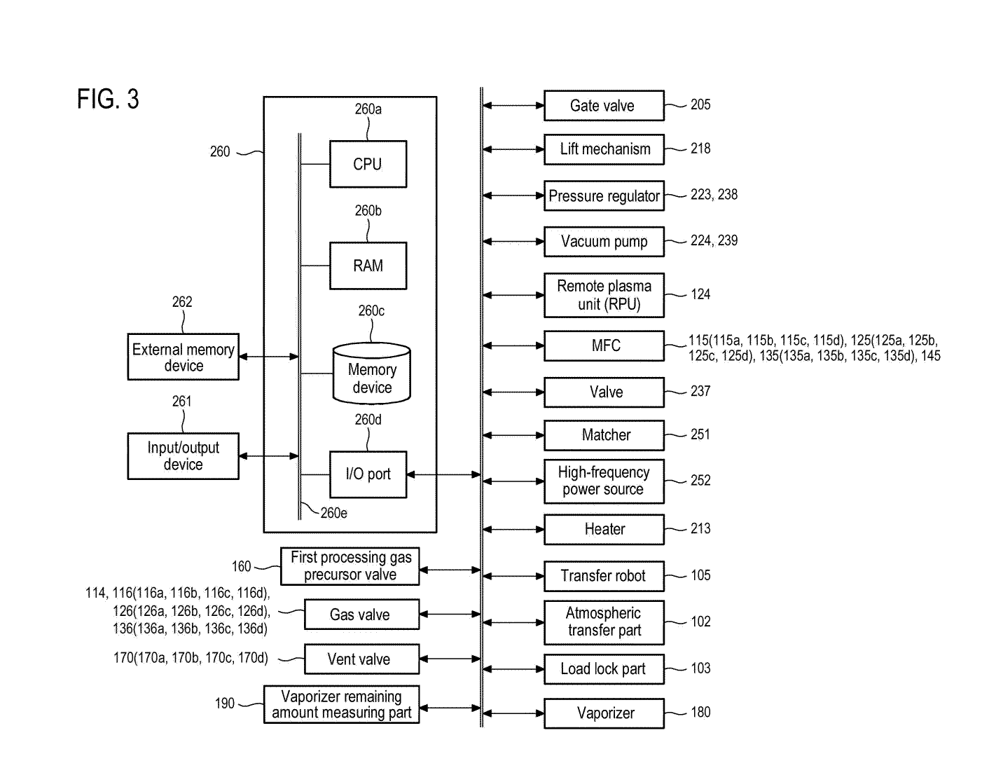

The outline of the controller 260 is illustrated in FIG. 3. The controller 260 as a control part (control means) is configured by a computer which includes a central processing unit (CPU) 260a, a random access memory (RAM) 260b, a memory device 260c and an I/O port 260d. The random access memory 260b, the memory device 260c and the I/O port 260d are configured to exchange data with the central processing unit 260a via an internal bus 260e. An input/output device 261 configured by, e.g., a touch panel, and an external memory device 262 may be connected to the controller 260.

The memory device 260c is configured by, for example, a flash memory or a hard disk drive (HDD). A control program for controlling the operation of the substrate processing apparatus, or a process recipe, in which substrate processing sequences and conditions are written, is readably stored in the memory device 260c. The process recipe is designed to obtain a predetermined result by causing the controller 260 to execute the respective sequences of a substrate processing process to be described later. The process recipe serves as a program. Hereinafter, the process recipe and the control program will be generally referred to as a “program”. By the term “program” used herein, it is intended to encompass only the process recipe, only the control program, or both. The random access memory 260b is configured as a memory area (work area) in which a program or data read by the central processing unit 260a is temporarily stored.

The I/O port 260d is connected to the gate valve 205, the lift mechanism 218, the heater 213, the pressure regulators 223 and 238, the vacuum pumps 224 and 239, the vaporizer 180, the vaporizer remaining amount measuring part 190, and so forth. Furthermore, the I/O port 260d may be connected to a below-described transfer robot 105, a below-described atmospheric transfer part 102, a below-described load lock part 103, the mass flow controllers 115 (115a, 115b, 115c and 115d), 125 (125a, 125b, 125c and 125d), 135 (135a, 135b, 135c and 135d) and 145, the valve 237, the gas valves 114, 116 (116a, 116b, 116c and 116d), 126 (126a, 126b, 126c and 126d), and 136 (136a, 136b, 136c, and 136d), the first processing gas precursor valve 160, the vent valve 170 (170a, 170b, 170c and 170d), the remote plasma unit (RPU) 124, the matcher 251, the high-frequency power source 252, and so forth.

The central processing unit 260a is configured to read out and execute the control program stored in the memory device 260c and to read out the process recipe from the memory device 260c in response to the input of an operation command from the input/output device 261. Furthermore, the central processing unit 260a is configured to, in conformity with the content of the read-out process recipe, perform the remaining amount measuring operation of the vaporizer remaining amount measuring part 190, the opening/closing operation of the gate valve 205, the lifting operation of the lift mechanism 218, the operation of supply of electric power to the heater 213, the pressure regulating operation of the pressure regulators 223 and 238, the on/off control of the vacuum pumps 224 and 239, the gas activating operation of the remote plasma unit 124, the flow rate control operation of the mass flow controllers 115 (115a, 115b, 115c and 115d), 125 (125a, 125b, 125c and 125d) and 135 (135a, 135b, 135c and 135d), the opening/closing control of the valve 237, the gas valves 114, 116 (116a, 116b, 116c and 116d), 126 (126a, 126b, 126c and 126d) and 136 (136a, 136b, 136c and 136d), the first processing gas precursor valve 160 and the vent valve 170 (170a, 170b, 170c and 170d), the power matching operation of the matcher 251, the on/off control of the high-frequency power source 252, and so forth.

The controller 260 is not limited to being configured as a dedicated computer but may be configured as a general-purpose computer. For example, the controller 260 according to the present embodiment may be configured by preparing an external memory device 262 (for example, a magnetic tape, a magnetic disc such as a flexible disc or a hard disc, an optical disc such as a CD or DVD, a magneto-optical disc such as an MO, or a semiconductor memory such as a USB memory or a memory card) which stores the aforementioned program, and installing the program on a general-purpose computer using the external memory device 262. However, a means for supplying the program to the computer is not limited to the case in which the program is supplied through the external memory device 262. For example, the program may be supplied through the use of a communication means such as the Internet or a dedicated line without having to go through the external memory device 262. The memory device 260c or the external memory device 262 is configured as a non-transitory computer-readable recording medium. Hereinafter, these means for supplying the program will be simply referred to as a “recording medium”. By the term “recording medium” used herein, it is intended to encompass only the memory device 260c, only the external memory device 262, or both.

### (2) Substrate Processing Process

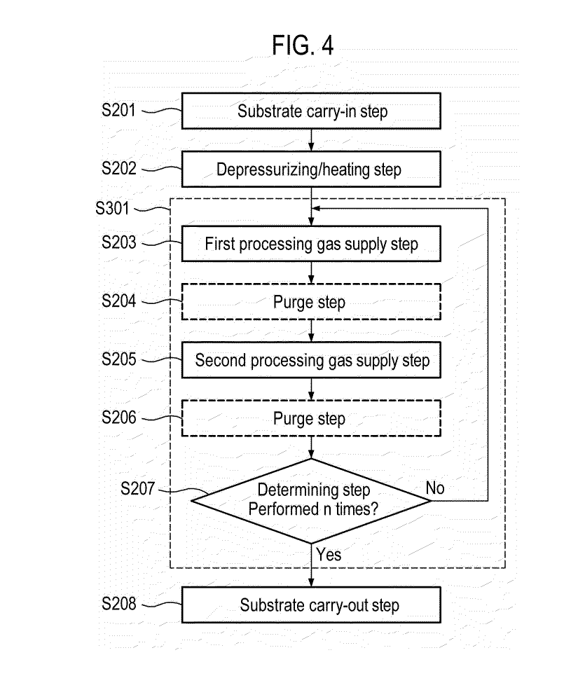

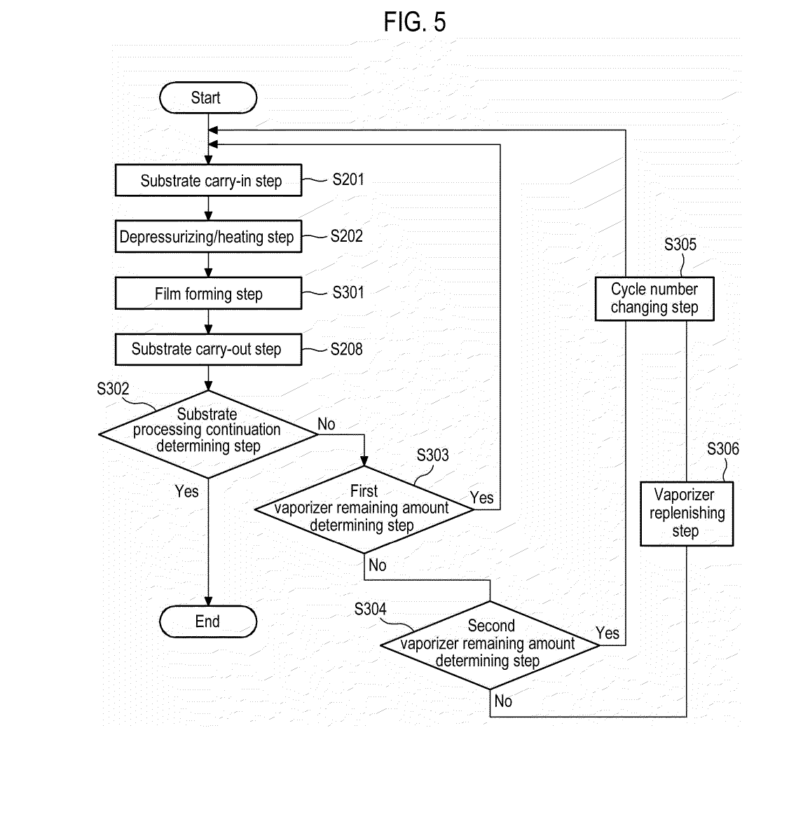

Next, an example of a substrate processing process will be described by taking, as an example, the formation of a silicon oxide film as a silicon-containing film, which is one of the semiconductor device manufacturing processes. Examples of sequences of the substrate processing process are illustrated in FIGS. 4 and 5.

FIG. 4 is a sequence diagram illustrating one example of the substrate processing process implemented by the substrate processing apparatus according to the present embodiment. As illustrated in FIG. 4, the substrate processing process includes at least a substrate carry-in step S201, a film forming step S301 and a substrate carry-out step S208. Hereinafter, the respective steps will be described in detail.

### (Substrate Carry-in Step S201)

When forming a film, the wafer 200 is first carried into the processing chamber 201. Specifically, the substrate support part 210 is moved down by the lift mechanism 218 such that the lift pins 207 protrude upward from the through-holes 214 beyond the upper surface of the substrate support part 210. After the internal pressure of the processing chamber 201 is regulated to a predetermined pressure, the gate valve 205 is opened. The wafer 200 is carried in from the gate valve 205 and is mounted on the lift pins 207. After mounting the wafer 200 on the lift pins 207, the substrate support part 210 is moved up to a predetermined position by the lift mechanism 218, whereby the wafer 200 is transferred from the lift pins 207 to the substrate support part 210.

### (Depressurizing/Heating Step S202)

Subsequently, the interior of the processing chamber 201 is evacuated through the exhaust pipe 222 so that the internal pressure of the processing chamber 201 becomes a predetermined pressure (vacuum level). At this time, the opening degree of the APC valve as the pressure regulator 223 is feed-back controlled based on the pressure value measured by a pressure sensor. Furthermore, the amount of electric power supplied to the heater 213 is feed-back controlled based on the temperature value detected by a temperature sensor (not illustrated) so that the internal temperature of the processing chamber 201 becomes a predetermined temperature. Specifically, a susceptor is heated in advance and a predetermined time is allowed to elapse after a change in the temperature of the wafer 200 or the susceptor becomes zero. During this time, the moisture remaining within the processing chamber 201 or the gas desorbed from a member is removed by the vacuum exhaust or the purge performed by the supply of a N₂ gas. In this way, the preparation which precedes a film forming process is finished. In addition, when evacuating the interior of the processing chamber 201 at a predetermined pressure, it may be possible to first vacuum-exhaust the processing chamber 201 to a reachable vacuum level.

### (Film Forming Step S301)

Subsequently, a step of forming a desired film on the wafer 200 is performed. Details of a film forming step S301 will be described with reference to FIG. 4.

After the wafer 200 is mounted on the substrate support part 210 and after the internal atmosphere of the processing chamber 201 is stabilized, steps S203 to S207 are performed.

### (First Processing Gas Supply Step S203)

At a first processing gas supply step S203, a dichlorosilane (SiH₂Cl₂: DCS) gas as a first processing gas as a first processing gas (a precursor gas) (a silicon-containing gas) is supplied from a first processing gas supply system into the processing chamber 201. Specifically, the gas valve 114 is opened and the carrier gas whose flow rate is adjusted to a predetermined flow rate by the mass flow controller 145 is supplied to the vaporizer 180. By causing DCS to bubble, the DCS is gasified. The DCS gas thus gasified is supplied to the substrate processing apparatus 100 after the flow rate of the DCS gas is adjusted by the mass flow controller 115. The DCS gas whose flow rate is adjusted is supplied from the gas supply holes 234a of the shower head 234 into the depressurized processing chamber 201. Furthermore, the interior of the processing chamber 201 is continuously evacuated by the exhaust system, thereby controlling the internal pressure of the processing chamber 201 so as to become a predetermined pressure (a first pressure). At this time, the DCS gas to be supplied onto the wafer 200 is supplied into the processing chamber 201 at a predetermined pressure (a first pressure of, e.g., 100 Pa or more and 20,000 Pa or less). In this way, the DCS is supplied onto the wafer 200. By supplying the DCS, a silicon-containing layer is formed on the wafer 200. The silicon-containing layer refers to a layer which contains silicon (Si) or a layer which contains silicon (Si) and chlorine (Cl).

### (Purge Step S204)

After the silicon-containing layer is formed on the wafer 200, the gas valve 116 of the first gas supply pipe 111 is closed to stop the supply of the DCS gas. At this time, the valve 237 of the exhaust pipe 236 is opened and the gas existing within the buffer space 232 is exhausted through the exhaust pipe 236 by the vacuum pump 239. In this case, the vacuum pump 239 is operated in advance and is continuously operated at least until the end of the substrate processing process. During the exhaust, the internal pressure of the exhaust pipe 236 and the shower head 234 (the exhaust conductance) is controlled by the APC valve 238. The APC valve 238 and the vacuum pump 239 may be controlled so that the exhaust conductance from the first exhaust system in the buffer space 232 becomes higher than the conductance of the vacuum pump 224 through the processing chamber 201. By virtue of this adjustment, there is formed a gas flow which moves from the center of the buffer space 232 toward the shower head exhaust port 231b. By doing so, the gas adhering to the wall of the buffer space 232 or the gas floating within the buffer space 232 may be exhausted from the first exhaust system with no entry into the processing chamber 201. In addition, the internal pressure of the buffer space 232 and the internal pressure of the processing chamber 201 (the exhaust conductance) may be adjusted so as to suppress the backflow of the gas from the processing chamber 201 into the buffer space 232.

At the purge step, instead of exhausting the gas by mere evacuation, the exhaust process may be performed by supplying an inert gas into the buffer space 232 and pushing out the remaining gas. Moreover, the evacuation and the supply of an inert gas may be performed in combination. In addition, the evacuation and the supply of an inert gas may be alternately performed.

At the purge step, the vacuum pump 224 is continuously operated and the gas existing within the processing chamber 201 is exhausted by the vacuum pump 224. Furthermore, the opening degree of the APC valve 223 may be adjusted so that the exhaust conductance from the processing chamber 201 to the vacuum pump 224 becomes higher than the exhaust conductance to the buffer space 232. By adjusting the opening degree of the APC valve 223 in this way, there is formed a gas flow which moves toward the second exhaust system via the processing chamber 201. This makes it possible to exhaust the gas remaining within the processing chamber 201. In this case, if an inert gas is supplied by opening the gas valve 136 and controlling the mass flow controller 135, it becomes possible to reliably supply the inert gas onto the substrate. Thus, the removal efficiency of the gas remaining on the substrate grows higher.

After a predetermined time elapses, the valve 136 is closed to stop the supply of the inert gas and the valve 237 is closed to disconnect the shower head 234 and the vacuum pump 239.

More specifically, after a predetermined time elapses, the valve 237 may be closed while continuously operating the vacuum pump 224. By doing so, the flow moving toward the second exhaust system via the processing chamber 201 is not affected by the first exhaust system. It is therefore possible to reliably supply the inert gas onto the substrate. This makes it possible to further enhance the removal efficiency of the gas remaining on the substrate.

Furthermore, the purge of the processing chamber refers to not only the exhaust of the gas by mere evacuation but also the operation of pushing out the processing gas by the supply of an inert gas. Accordingly, at the purge step, the exhaust operation may be performed by supplying an inert gas into the buffer space 232 and pushing out the remaining gas. Moreover, the evacuation and the supply of an inert gas may be performed in combination. In addition, the evacuation and the supply of an inert gas may be alternately performed.

In this case, the flow rate of an N₂ gas supplied into the processing chamber 201 need not be made large. For example, by supplying the N₂ gas in an amount substantially equal to the volume of the processing chamber 201, it is possible to perform the purge without adversely affecting the next step. By not completely purging the interior of the processing chamber 201 in this way, it is possible to shorten the purge time and to improve the manufacturing throughput. It is also possible to reduce the consumption of the N₂ gas to a necessary minimum level.

Similar to the case where the precursor gas is supplied to the wafer 200, the temperature of the heater 213 is set to become a constant temperature which falls within a range of 200 to 750 degrees C., specifically 300 to 600 degrees C. and more specifically 300 to 550 degrees C. The supply flow rate of the N₂ gas as a purge gas supplied from each of the inert gas supply systems is set at a flow rate which falls within a range of, e.g., 100 to 20,000 sccm. In addition to the N₂ gas, a rare gas such as Ar, He, Ne or Xe may be used as the purge gas.

### (Second Processing Gas Supply Step S205)

After the first processing chamber purge step, the valve 126 is opened and an oxygen-containing gas (O₂ gas) as a second processing gas (a reaction gas) is supplied into the processing chamber 201 through the gas introduction port 241, the buffer space 232 and the dispersion holes 234a. Since the oxygen-containing gas is supplied into the processing chamber 201 through the buffer space 232 and the dispersion holes 234a, it is possible to uniformly supply the gas onto the substrate. Therefore, it is possible to make the film thickness uniform. When supplying the second processing gas, an activated oxygen-containing gas may be supplied into the processing chamber 201 via the remote plasma unit (RPU) 124 as an activating part (or an exciting part).

In this case, the mass flow controller 125 is controlled to a target heating temperature so that the flow rate of the O₂ gas becomes a predetermined flow rate. The supply flow rate of the O₂ gas may be, for example, 100 sccm or more and 10,000 sccm or less. By appropriately adjusting the opening degree of the APC valve 223, the internal pressure of the processing container 202 is set at a predetermined pressure. When the O₂ gas flows through the remote plasma unit 124, the remote plasma unit 124 is kept in an on-state (a power-on state) so that the O₂ gas is activated (excited).

If the O₂ gas is supplied to the silicon-containing layer formed on the wafer 200, the silicon-containing layer is modified. Furthermore, if the activated O₂ gas is supplied onto the wafer 200 by installing the remote plasma unit 124, it is possible to form a modified layer having a larger thickness.

Depending on, e.g., the internal pressure of the processing chamber 201, the flow rate of the O₂ gas, the temperature of the wafer 200 and the power supply state of the remote plasma unit 124, the modified layer is formed at a predetermined thickness, a predetermined distribution and a predetermined depth of infiltration of a nitrogen component or the like into the silicon-containing layer.

After a predetermined time elapses, the valve 126 is closed and the supply of the O₂ gas is stopped.

### (Purge Step S206)

After the supply of the O₂ gas is stopped, the valve 237 is opened and the gas existing within the buffer space 232 is exhausted through the exhaust pipe 236 by the vacuum pump 239. During the exhaust, the internal pressure of the exhaust pipe 236 and the shower head 234 (the exhaust conductance) is controlled by the APC valve 238. The APC valve 238 and the vacuum pump 239 may be controlled so that the exhaust conductance from the first exhaust system in the buffer space 232 becomes higher than the conductance of the vacuum pump 224 through the processing chamber 201. By virtue of this adjustment, a gas flow which moves from the center of the buffer space 232 toward the shower head exhaust port 231b is formed. By doing so, the gas adhering to the wall of the buffer space 232 or the gas floating within the buffer space 232 may be exhausted from the first exhaust system with no entry into the processing chamber 201. In addition, the internal pressure of the buffer space 232 and the internal pressure of the processing chamber 201 (the exhaust conductance) may be adjusted so as to suppress the backflow of the gas from the processing chamber 201 into the buffer space 232.

The purge of the second shower head purge step may be performed similar to the purge of the first shower head purge step.

At the purge step, the vacuum pump 224 is continuously operated and the gas existing within the processing chamber 201 is exhausted by the vacuum pump 224. Furthermore, the opening degree of the APC valve 223 may be adjusted so that the exhaust conductance from the processing chamber 201 to the vacuum pump 224 in the processing chamber 201 becomes higher than the exhaust conductance to the buffer space 232. By adjusting the opening degree of the APC valve 223 in this way, there is formed a gas flow which moves toward the second exhaust system via the processing chamber 201. This makes it possible to exhaust the gas remaining within the processing chamber 201. In this case, if an inert gas is supplied by opening the gas valve 136 and controlling the mass flow controller 135, it becomes possible to reliably supply the inert gas onto the substrate. Thus, the removal efficiency of the gas remaining on the substrate grows higher.

After a predetermined time elapses, the valve 136 is closed to stop the supply of the inert gas and the valve 237 is closed to disconnect the shower head 234 and the vacuum pump 239.

More specifically, after a predetermined time elapses, the valve 237 may be closed while continuously operating the vacuum pump 224. By doing so, the flow moving toward the second exhaust system via the processing chamber 201 is not affected by the first exhaust system. It is therefore possible to reliably supply the inert gas onto the substrate. This makes it possible to further enhance the removal efficiency of the gas remaining on the substrate.

Furthermore, the purge of the processing chamber refers to not only the exhaust of the gas by mere evacuation but also the operation of pushing out the processing gas by the supply of an inert gas. Accordingly, at the purge step, the exhaust operation may be performed by supplying an inert gas into the buffer space 232 and pushing out the remaining gas. Moreover, the evacuation and the supply of an inert gas may be performed in combination. In addition, the evacuation and the supply of an inert gas may be alternately performed.

In this case, the flow rate of an N₂ gas supplied into the processing chamber 201 need not be made large. For example, by supplying the N₂ gas in an amount substantially equal to the volume of the processing chamber 201, it is possible to perform the purge without adversely affecting the next step. By not completely purging the interior of the processing chamber 201 in this way, it is possible to shorten the purge time and to improve the manufacturing throughput. It is also possible to reduce the consumption of the N₂ gas to a necessary minimum level.

### (Determining Step S207)

After the purge step S207 is completed, the controller 260 determines whether the film forming step S301 (steps S203 to S206) was performed a predetermined number of cycles n. That is to say, the controller 260 determines whether a film having a desired thickness was formed on the wafer 200.

If the film forming step S301 was not performed a predetermined number of times (if no at step S207), the cycle of steps S203 to S206 is repeated. If the film forming step S301 was performed the predetermined number of times (if yes at step S207), the film forming step S301 is completed and a substrate carry-out step S208 is performed.

### (Substrate Carry-Out Step S208)

After the film forming step S301 comes to an end, the substrate support part 210 is moved down by the lift mechanism 218 so that the lift pins 207 protrude upward from the through-holes 214 beyond the upper surface of the substrate support part 210. Furthermore, after the internal pressure of the processing chamber 201 is regulated to a predetermined pressure, the gate valve 205 is opened and the wafer 200 is transferred from above the lift pins 207 and outside of the gate valve 205. Thereafter, a substrate processing continuation determining step S302 is performed.

### (Substrate Processing Continuation Determining Step S302)

At the substrate processing continuation determining step S302, determination is made as to whether the substrate processing process was performed a predetermined number of times. For example, determination is made as to whether the processing was performed by the number of processing times corresponding to the number of substrates stored within a front opening unified pod (FOUP). If the number of processing times is equal to or larger than a predetermined number of times (if yes at step S302), the gate valve 205 is closed and the substrate processing process is completed. If the number of processing times is smaller than the predetermined number of times (if no at step S302), a first vaporizer remaining amount determining step S303 is performed.

### (First Vaporizer Remaining Amount Determining Step S303)

At the first vaporizer remaining amount determining step S303, measurement and determination is made as to whether the amount of the first processing gas precursor retained within the vaporizer 180 is equal to or larger than a first prescribed amount. If the amount of the first processing gas precursor is equal to or larger than the first prescribed amount, it is determined that the answer at step S303 is yes. Then, the substrate carry-in step S201 is executed and the substrate processing process is performed. If the amount of the first processing gas precursor is smaller than the first prescribed amount, it is determined that the answer at step S303 is no. Then, a second vaporizer remaining amount determining step S304 is performed. The measurement of the amount of the first processing gas precursor retained within the vaporizer 180 is performed by the vaporizer remaining amount measuring part 190. The vaporizer remaining amount measuring part 190 measures the amount of the first processing gas precursor based on the weight or the liquid surface height of the first processing gas precursor retained within the vaporizer 180. According to this measurement method, it is possible to solve the following problem which may be generated when the amount of the first processing gas precursor is measured based on the cumulative flow rate in the mass flow controller 115 or the number of processing times in the processing chamber 201. For example, in the case where the liquid surface height within the vaporizer 180 is changed, the distance at which the carrier gas passes through the liquid as indicated by a broken line arrow in FIG. 2 and the distance at which the carrier gas passes through the space defined above the liquid surface within the vaporizer 180 are changed. This poses a problem in that the amount of the first processing gas precursor captured by the carrier gas is changed and the partial pressures of the first processing gas and the carrier gas are changed. For example, if the distance at which the carrier gas passes through the liquid is shortened, the generation amount of the first processing gas is reduced. If the space defined above the liquid surface is increased, there may be a case where the first processing gas stays within the vaporizer 180.

### (Second Vaporizer Remaining Amount Determining Step S304)

At the second vaporizer remaining amount determining step S304, determination is made as to whether the amount of the processing gas precursor retained within the vaporizer 180 is equal to or larger than a second prescribed amount. If the amount of the processing gas precursor is equal to or larger than the second prescribed amount, it is determined that the answer at step S304 is yes. Then, a cycle number changing step S305 is performed. If the amount of the processing gas precursor is smaller than the second prescribed amount, it is determined that the answer at step S304 is no. Then, a replenishing step S306 is performed with respect to the vaporizer 180.

### (Cycle Number Changing Step S305)

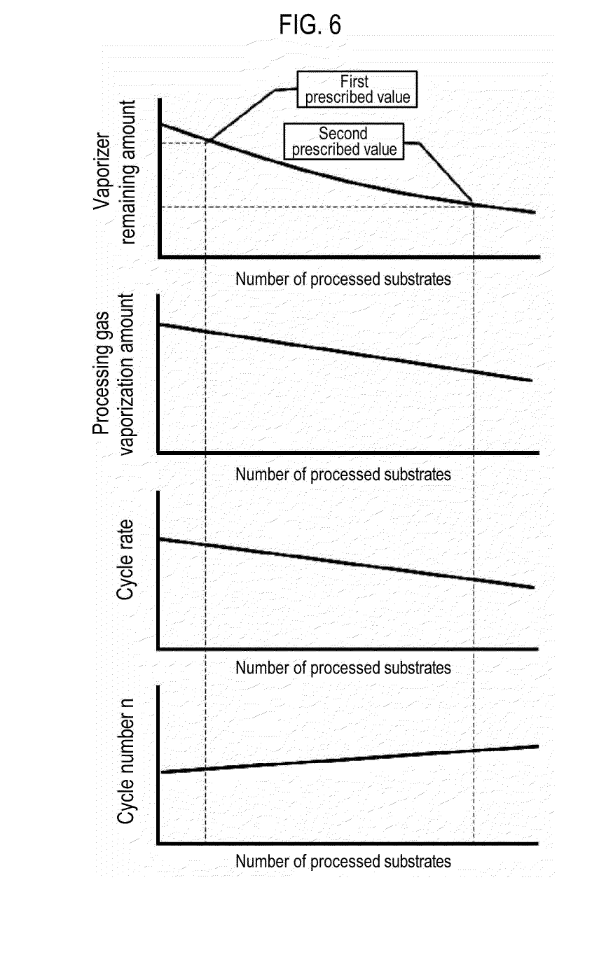

At the cycle number changing step S305, the cycle number n determined at the determining step S207 is set. As described above and as illustrated in FIG. 6, if the number of processed substrates increases, the vaporization amount of the processing gas is reduced. Thus, the film thickness per one cycle of the film forming step S301 (the cycle rate) is reduced. This makes it impossible to obtain a target film thickness. Accordingly, the cycle number n is increased to obtain the target film thickness. After setting the cycle number n, the substrate carry-in step S201 is executed and the substrate processing process is performed.

### (Vaporizer Replenishing Step S306)

At the vaporizer replenishing step S306, the precursor is replenished so that the amount of the precursor retained within the vaporizer 180 becomes a predetermined amount. For example, the precursor is replenished so that the remaining amount of the precursor in the vaporizer 180 becomes an initial value. After the vaporizer replenishing step S306, the cycle number changing step S305 is performed to change the cycle number n. For example, the cycle number n is reset to an initial value. After the cycle number changing step S305, the substrate carry-in step S201 is executed and the substrate processing process is performed.

### <Effects According to the Present Embodiment>

The present embodiment may have one or more of the following effects.

(a) By measuring the remaining amount of the precursor in the vaporizer 180, it is possible to measure the partial pressure ratio of the first processing gas and the carrier gas.
(b) By measuring the remaining amount of the precursor in the vaporizer 180 and adjusting the cycle number, it is possible to maintain the film thickness constant in each of the substrates (in each of the processes).
(c) By measuring the remaining amount of the precursor in the vaporizer 180 based on the weight thereof, it is possible to measure the remaining amount even if the first processing gas precursor is a solid.

### Second Embodiment

While the first embodiment has been specifically described above, the present disclosure is not limited to the above-described embodiment and may be differently modified without departing from the spirit thereof.

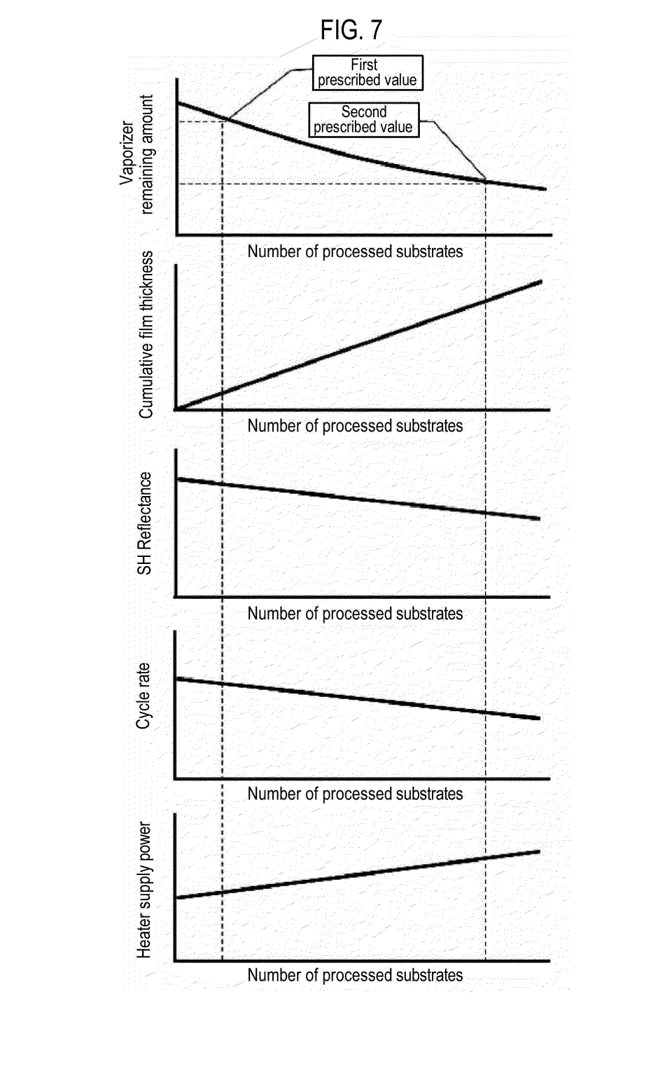

The foregoing descriptions have been made on the case where the cause of the change in the cycle rate is the change in the vaporization amount. In addition to this cause, there may be a cause illustrated in FIG. 7. As the number of the processed substrates increases, the cumulative film thickness within the processing chamber 201 grows larger. Thus, the reflectance of radiant heat (the SH reflectance) of the shower head 234 decreases. It becomes impossible to reflect the heat irradiated from the heater 213 toward the wafer 200. The temperature of the surface of the wafer 200 is lowered. As a result, the reaction probability in the vicinity of the surface of the wafer 200 is reduced and the cycle rate is reduced. In this case, even if the cycle number is increased as in the first embodiment, it may be impossible to obtain the effects. For example, there may be generated a phenomenon that the dispersion holes 234a are narrowed by the film deposited on the shower head 234. This makes it impossible to obtain the desired flow rate of the gas supplied from the shower head 234 into the processing chamber 201. Therefore, it may be impossible to obtain the effects provided by the adjustment of the cycle number. In this case, as illustrated in FIG. 7, the electric power supplied to the heater 213 may be increased such that the desired reaction is generated in the vicinity of the surface of the wafer 200.

Furthermore, by combining the adjustment of the electric power supplied to the heater 213 and the cycle number changing step, both of which are described in the first embodiment, it becomes possible to further adjust the film thickness.

In addition, the reduction in the temperature of the surface of the wafer 200 may vary within the plane of the wafer 200. In this case, the heater 213 may be divided into an inner heater and an outer heater. Different levels of electric power may be supplied to the inner heater and the outer heater so as to control the temperature in the vicinity of the surface of the wafer 200.

### Third Embodiment

While the second embodiment has been specifically described above, the present disclosure is not limited to the above-described embodiment and may be differently modified without departing from the spirit thereof

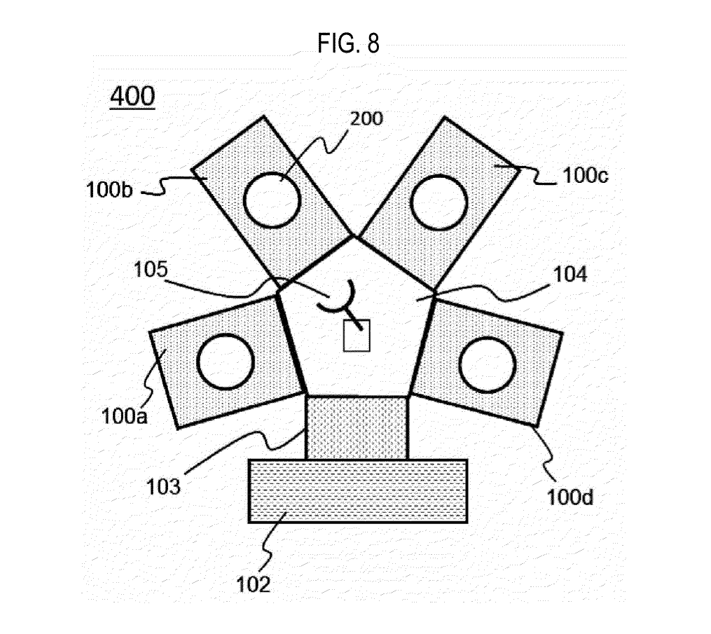

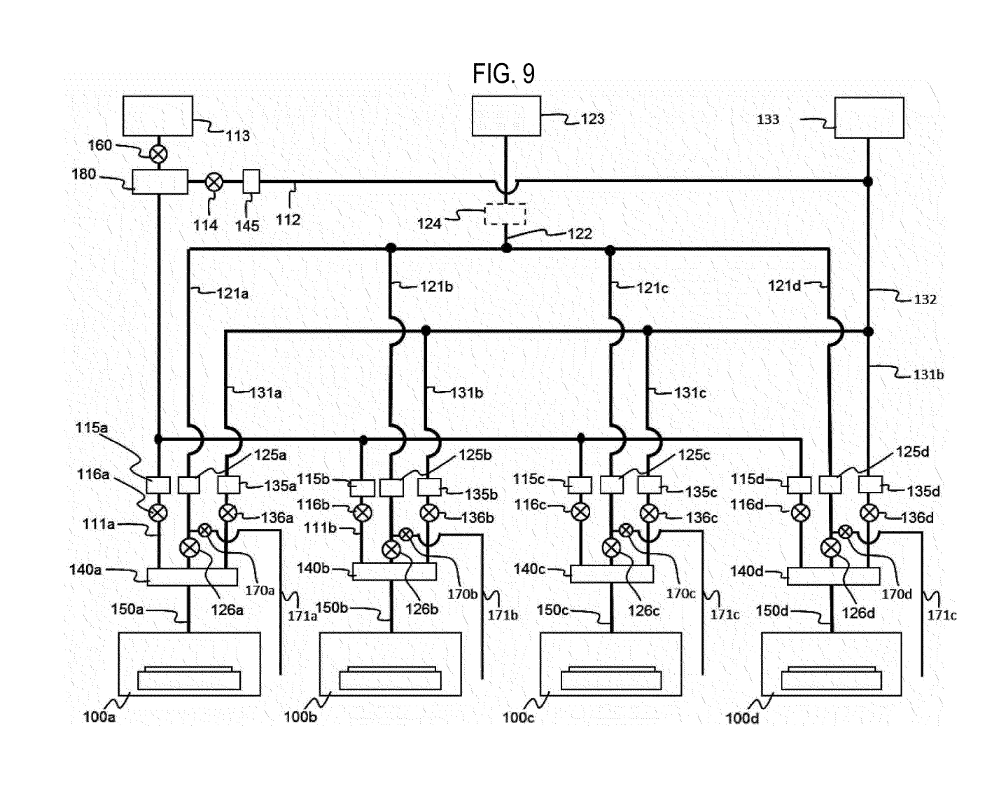

For example, it may be possible to employ the structure of a substrate processing system illustrated in FIGS. 8 and 9.

Descriptions will now be made on a substrate processing system 400 in which, as illustrated in FIG. 8, four substrate processing apparatuses 100a, 100b, 100c and 100d are installed within a vacuum transfer chamber 104. The same kind of processing is performed in the respective substrate processing apparatuses 100a, 100b, 100c and 100d. Wafers 200 are sequentially transferred to the respective substrate processing apparatuses 100a, 100b, 100c and 100d by a vacuum transfer robot 105 installed in the vacuum transfer chamber 104. Furthermore, the wafers 200 are carried from an atmospheric transfer part 102 into the vacuum transfer chamber 104 via a load lock part 103. While there is illustrated the case where four substrate processing apparatuses are installed, the present disclosure is not limited thereto. It is only necessary that the two or more substrate processing apparatuses are installed. Five or more substrate processing apparatuses, e.g., eight substrate processing apparatuses, may be installed.

Next, a gas supply system installed in the substrate processing system 400 will be described with reference to FIG. 9. The gas supply system includes a first processing gas supply system (a processing gas supply system), a second processing gas supply system (a reaction gas supply system), a third gas supply system (a purge gas supply system), etc. Descriptions will be made on the configurations of the respective gas supply systems.

### (First Processing Gas Supply System)

As illustrated in FIG. 9, a vaporizer 180, mass flow controllers (MFC) 115a, 115b, 115c and 115d and gas valves 116a, 116b, 116c and 116d are installed between a processing gas source 113 and the respective substrate processing apparatuses. The vaporizer 180, the mass flow controllers 115a, 115b, 115c and 115d and the gas valves 116a, 116b, 116c and 116d are connected by a common processing gas pipe 112, processing gas supply pipes 111a, 111b, 111c and 111d, etc. A first processing gas supply system is configured by the vaporizer 180, the mass flow controllers 115a, 115b, 115c and 115d, the gas valves 116a, 116b, 116c and 116d and the processing gas supply pipes 111a, 111b, 111c and 111d. Furthermore, the processing gas source 113 may be included in the first processing gas supply system. Moreover, a carrier gas supply pipe 112, a mass flow controller 145 and a first processing gas precursor valve 160 may be included in the first processing gas supply system. In addition, the number of the respective components may be increased or reduced depending on the number of the substrate processing apparatuses installed in the substrate processing system.

### (Second Processing Gas Supply System)

As illustrated in FIG. 9, mass flow controllers 125a, 125b, 125c and 125d and gas valves 126a, 126b, 126c and 126d are installed between a reaction gas source 123 and the respective substrate processing apparatuses. The mass flow controllers 125a, 125b, 125c and 125d and the gas valves 126a, 126b, 126c and 126d are connected by a common reaction gas pipe 122, reaction gas supply pipes 121a, 121b, 121c and 121d, etc. A second processing gas supply system is configured by the mass flow controllers 125a, 125b, 125c and 125d, the gas valves 126a, 126b, 126c and 126d, the common reaction gas pipe 122, the reaction gas supply pipes 121a, 121b, 121c and 121d, etc. Furthermore, the reaction gas source 123 may be included in the second processing gas supply system. Moreover, the number of the respective components may be increased or reduced depending on the number of the substrate processing apparatuses installed in the substrate processing system. In addition, a remote plasma unit (RPU) 124 as an activating part may be installed so as to activate a second processing gas.

Furthermore, vent lines 171a, 171b, 171c and 171d and vent valves 170a, 170b, 170c and 170d may be installed at the upstream side of the gas valves 126a, 126b, 126c and 126d so that the reaction gas can be exhausted. By installing the vent lines, it is possible to exhaust a deactivated reaction gas or a reaction gas having low reactivity without going through the processing chamber. This makes it possible to improve the processing uniformity between the substrate processing apparatuses.

(Third Gas Supply system)

As illustrated in FIG. 9, mass flow controllers 135a, 135b, 135c and 135d and gas valves 136a, 136b, 136c and 136d are installed between a purge gas (inert gas) source 133 and the respective substrate processing apparatuses. The mass flow controllers 135a, 135b, 135c and 135d and the gas valves 136a, 136b, 136c and 136d are connected by a common purge gas (inert gas) pipe 132, purge gas (inert gas) supply pipes 131a, 131b, 131c and 131d, etc. A third gas supply system is configured by the mass flow controllers 135a, 135b, 135c and 135d, the gas valves 136a, 136b, 136c and 136d, the common purge gas (inert gas) pipe 132, the purge gas (inert gas) supply pipes 131a, 131b, 131c and 131d, etc. Furthermore, the purge gas (inert gas) source 133 may be included in the third gas supply system (or the purge gas supply system). Moreover, the number of the respective components may be increased or reduced depending on the number of the substrate processing apparatuses installed in the substrate processing system.

The present inventors have found that this substrate processing system has the following problem. In this substrate processing system, one processing gas source 113 and one vaporizer 180 are shared by a plurality of substrate processing apparatuses 100a, 100b, 100c and 100d. In this configuration, if the vaporization amount in the vaporizer 180 is changed due to the change in the remaining amount of the precursor in the vaporizer 180, there is posed a problem in that a difference is generated between the processes performed in the respective substrate processing apparatuses 100a, 100b, 100c and 100d and the processes become different between the wafers 200.

Even in this case, by performing the first vaporizer remaining amount determining step S303, the second vaporizer remaining amount determining step S304, the cycle number changing step S305 and the vaporizer replenishing step S306 as in the above-described embodiments, it becomes possible to perform the desired processing with respect to the respective wafers 200.

While the manufacturing process of the semiconductor device has been described above, the present disclosure may be applied to the processes other than the manufacturing process of the semiconductor device. For example, the present disclosure may be applied to a manufacturing process of a liquid crystal device or a plasma processing process of a ceramic substrate.

While descriptions have been made on the method of forming the film by alternately supplying the precursor gas and the reaction gas, the present disclosure may be applied to other methods. For example, the precursor gas and the reaction gas may be supplied so that the supply timings thereof overlap with each other.

While descriptions have been made on the film forming process, the present disclosure may be applied to other processes. For example, the present disclosure may be applied to a case where the surface of a substrate or the film formed on the substrate is subjected to a plasma-oxidizing process or a plasma-nitriding process using only a reaction gas. Furthermore, the present disclosure may be applied to a plasma-annealing process using only a reaction gas.

While descriptions have been made on the film forming method in which two kinds of gases, i.e., the precursor gas and the reaction gas are used, the present disclosure may be applied to other methods. In some embodiments, the present disclosure may be applied to a film forming method in which three or more kinds of gases are sequentially supplied. In this case, remaining amounts of two gases among the three or more kinds of gases may be measured and a number of cycles for supplying the three or more kinds of gases may be adjusted based on the measured remaining amounts. For example, in a film forming method in which a silicon-containing gas, an oxygen-containing gas, and a carbon-containing gas are sequentially supplied, a remaining amount of the silicon-containing gas, a remaining amount of the carbon-containing gas, or both may be measured and a number of cycles for supplying the gases may be adjusted based on the measured remaining amounts.

In the above-described embodiments, there has been illustrated the example where the oxide film (the silicon oxide (SiOₓ) film) used as a spacer film is formed using the DCS gas and the O₂ gas. However, the present disclosure is not limited thereto. Hexachlorodisilane ((Si₂Cl₆): HCDS) may be used as the first processing gas (the silicon precursor). For example, the oxide film may be a high dielectric constant (high-k) film used as a gate insulation film or a capacitor film. As another example, the oxide film may be a zirconium oxide (ZrₓO_{y}) film or a hafnium oxide (HfₓO_{y}) film.

In the above-described embodiments, remaining amounts of the liquid precursors are measured and the number of cycles is adjusted based on the measured remaining amounts. However, the present disclosure is not limited thereto. Remaining amounts of solid precursors may be measured, and a number of cycles for supplying the gases or an exposure time of the gases may be adjusted based on the measured remaining amounts. In some cases, it is hard to supplement the solid precursors in the middle of the substrate processing. Further, if the remaining amounts of the solid precursors are reduced, the vapor pressure may be decreased. Under the circumstances, in order to enhance the uniformity of processing per substrate, the exposure time other than the number of cycles for supplying the gases may be increased.

In the above-described embodiments, there has been illustrated the example where the number of cycles n for supplying the first processing gas is adjusted. However, the present disclosure is not limited thereto. For example, a number of cycles n for supplying the second processing gas may be adjusted. Alternatively, a number of cycles n for supplying both of the first processing gas and the second processing gas may be adjusted.

### <Aspects of Present Disclosure>

Hereinafter, some aspects of the present disclosure are additionally described as supplementary notes.

### <Supplementary Note 1>

According to one aspect of the present disclosure, there is provided a substrate processing apparatus, including:

a processing chamber configured to accommodate a substrate therein;

a first processing gas supply part configured to supply a first processing gas to the substrate, the first processing gas supply part including a vaporizer configured to vaporize a first processing gas precursor into the first processing gas;

a second processing gas supply part configured to supply a second processing gas to the substrate;

a vaporizer remaining amount measuring part configured to measure a remaining amount of the first processing gas precursor within the vaporizer; and

a control part configured to adjust a number of cycles for supplying the first processing gas and the second processing gas based on the remaining amount of the first processing gas precursor.

### <Supplementary Note 2>

In the apparatus of Supplementary Note 1, the vaporizer remaining amount measuring part may be configured to measure the remaining amount of the first processing gas precursor by measuring a weight of the first processing gas precursor.

### <Supplementary Note 3>

In the apparatus of Supplementary Note 1 or 2, when the remaining amount of the first processing gas precursor within the vaporizer is smaller than a first preset amount and equal to or greater than a second preset amount, the control part may be configured to adjust the number of cycles for supplying the first processing gas and the second processing gas to be equal to or greater than a predetermined number.

### <Supplementary Note 4>

In the apparatus of Supplementary Note 1 or 2, when the remaining amount of the first processing gas precursor within the vaporizer is smaller than a second preset amount, the control part may be configured to replenish the vaporizer with the first processing gas precursor and reset the number of cycles.

### <Supplementary Note 5>

The apparatus of any one of Supplementary Notes 1 to 4 may further include:

a substrate mounting table including a heating part configured to heat the substrate,

wherein when the remaining amount is smaller than a first preset amount and equal to or greater than a second preset amount, the control part may be configured to increase electric power supplied to the heating part.

### <Supplementary Note 6>

According to another aspect of the present disclosure, there is provided a method of manufacturing a semiconductor device, including:

accommodating a substrate within a processing chamber;

supplying a first processing gas to the substrate;

supplying a second processing gas to the substrate;

measuring a remaining amount of a first processing gas precursor within a vaporizer; and

adjusting a number of cycles for supplying the first processing gas and the second processing gas based on the remaining amount of the first processing gas precursor.

### <Supplementary Note 7>

In the method of Supplementary Note 6, in the act of measuring the remaining amount, a weight of the first processing gas precursor may be measured.

### <Supplementary Note 8>

The method of Supplementary Note 6 or 7 may further include adjusting the number of cycles for supplying the first processing gas and the second processing gas to be equal to or greater than a predetermined number when the remaining amount is smaller than a first preset amount and equal to or greater than a second preset amount.

### <Supplementary Note 9>

The method of Supplementary Note 6 or 7 may further include replenishing the vaporizer with the first processing gas precursor and resetting the number of cycles for supplying the first processing gas and the second processing gas when the remaining amount is smaller than a second preset amount.

### <Supplementary Note 10>

The method of any one of Supplementary Notes 6 to 8 may further include increasing electric power supplied to a heating part configured to heat the substrate when the remaining amount is smaller than a first preset amount and equal to or greater than a second preset amount.

### <Supplementary Note 11>

According to a further aspect of the present disclosure, there is provided a program which causes a computer to perform:

accommodating a substrate within a processing chamber;

supplying a first processing gas to the substrate;

supplying a second processing gas to the substrate;

measuring a remaining amount of a first processing gas precursor within a vaporizer; and

adjusting a number of cycles for supplying the first processing gas and the second processing gas based on the remaining amount of the first processing gas precursor.

### <Supplementary Note 12>

In the program of Supplementary Note 11 causes a computer to implement measuring a weight of the vaporizer in the process of measuring the remaining amount.

### <Supplementary Note 13>

The program of Supplementary Note 11 or 12 may cause the computer to implement adjusting the number of cycles for supplying the first processing gas and the second processing gas to be equal to or greater than a predetermined number when the remaining amount is smaller than a first preset amount and equal to or greater than a second preset amount.

### <Supplementary Note 14>

The program of Supplementary Note 11 or 12 may cause the computer to implement replenishing the vaporizer with the first processing gas precursor and resetting the number of cycles for supplying the first processing gas and the second processing gas when the remaining amount is smaller than a second preset amount.

### <Supplementary Note 15>

The program of any one of Supplementary Notes 11 to 13 may cause the computer to implement increasing electric power supplied to a heating part configured to heat the substrate when the remaining amount is smaller than a first preset amount and equal to or greater than a second preset amount.

### <Supplementary Note 16>

According to a still further aspect of the present disclosure, there is provided a non-transitory computer-readable recording medium which records a program configured to cause a computer to perform:

accommodating a substrate within a processing chamber;

supplying a first processing gas to the substrate;

supplying a second processing gas to the substrate;

measuring a remaining amount of a first processing gas precursor within a vaporizer; and

adjusting a number of cycles for supplying the first processing gas and the second processing gas based on the remaining amount of the first processing gas precursor.

According to the substrate processing apparatus, the method of manufacturing a semiconductor device and the recording medium of the present disclosure, it is possible to improve the characteristics of a film formed on a substrate and to enhance the manufacturing throughput.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing chamber configured to accommodate a substrate therein;
a first processing gas supply part configured to supply a first processing gas to the substrate, the first processing gas supply part including a vaporizer configured to vaporize a first processing gas precursor into the first processing gas;
a second processing gas supply part configured to supply a second processing gas to the substrate;
a vaporizer remaining amount measuring part configured to measure a remaining amount of the first processing gas precursor within the vaporizer; and
a control part configured to adjust a number of cycles for supplying the first processing gas and the second processing gas based on the remaining amount of the first processing gas precursor.

2. The apparatus of claim 1, wherein the vaporizer remaining amount measuring part is configured to measure the remaining amount of the first processing gas precursor by measuring a weight of the first processing gas precursor.

3. The apparatus of claim 1, wherein when the remaining amount of the first processing gas precursor within the vaporizer is smaller than a first preset amount and equal to or greater than a second preset amount, the control part is configured to adjust the number of cycles for supplying the first processing gas and the second processing gas to be equal to or greater than a predetermined number.

4. The apparatus of claim 2, wherein when the remaining amount of the first processing gas precursor within the vaporizer is smaller than a first preset amount and equal to or greater than a second preset amount, the control part is configured to adjust the number of cycles for supplying the first processing gas and the second processing gas to be equal to or greater than a predetermined number.

5. The apparatus of claim 1, wherein when the remaining amount of the first processing gas precursor within the vaporizer is smaller than a second preset amount, the control part is configured to replenish the vaporizer with the first processing gas precursor and reset the number of cycles.

6. The apparatus of claim 2, wherein when the remaining amount of the first processing gas precursor within the vaporizer is smaller than a second preset amount, the control part is configured to replenish the vaporizer with the first processing gas precursor and reset the number of cycles.

7. The apparatus of claim 1, further comprising:
a substrate mounting table including a heating part configured to heat the substrate,
wherein when the remaining amount is smaller than a first preset amount and equal to or greater than a second preset amount, the control part is configured to increase electric power supplied to the heating part.

8. The apparatus of claim 2, further comprising:
a substrate mounting table including a heating part configured to heat the substrate,
wherein when the remaining amount is smaller than a first preset amount and equal to or greater than a second preset amount, the control part is configured to increase electric power supplied to the heating part.

9. The apparatus of claim 3, further comprising:
a substrate mounting table including a heating part configured to heat the substrate,
wherein when the remaining amount is smaller than a first preset amount and equal to or greater than a second preset amount, the control part is configured to increase electric power supplied to the heating part.

10. The apparatus of claim 5, further comprising:
a substrate mounting table including a heating part configured to heat the substrate,
wherein when the remaining amount is smaller than a first preset amount and equal to or greater than a second preset amount, the control part is configured to increase electric power supplied to the heating part.
